(19) United States
(12) Patent Application Publication
(10) Pub. No.: US 2007/0029663 A1
(43) Pub. Date: Feb. 8, 2007

(54) Multilayered circuit substrate and semiconductor package structure using the same

(76) Inventors: Moon-Jung Kim, Gyeonggi-do (KR); Jong-Joo Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/371,155

(22) Filed: Mar. 7, 2006

(30) Foreign Application Priority Data
Aug. 8, 2005 (KR) 2005-72510

(51) Int. Cl. H01L 23/48; H01L 21/44

(52) U.S. Cl. 257/700; 438/126; 438/613; 257/738

(57) ABSTRACT

A multilayered circuit substrate and a semiconductor package using the multilayered circuit substrate are provided to increase the number of bonding pads arranged on the circuit substrate without reducing the pitch of the bonding pads, and to further increase the routing feasibility of high speed signals by the use of signal wirings instead of vias. An embodiment may include bonding pads provided on different layers, in which the bonding pads arranged on one layer are staggered with the bonding pad arranged on another layer. Ball lands may be connected to the bonding pads using wirings wherein the bonding pads connected to the signal wirings may be provided on the same layer as the corresponding ball lands.

### CROSS REFERENCE TO RELATED APPLICATIONS

This U.S. non-provisional application claims priority from Korean Patent Application No. 2005-72510 filed Aug. 8, 2005, the contents of which are incorporated herein by reference in their entirety.

### BACKGROUND

1. Field of the Invention

The present invention relates generally to semiconductor packaging technology, and more particularly, to a multilayered circuit substrate and a semiconductor package structure using the same.

2. Description of the Related Art

With the recent developments in the digital electronic industry, memory products have increasingly required higher speeds, higher integration, and the ability to multifunction. One method that is used to achieve these requirements is to use multilayered circuit substrates for the semiconductor packages in the memory products.

In conformity with this advancing trend of memory products, a package structure needs more bonding pads and ball terminals. As the quantity of bonding pads and ball terminals increases for a given area of a circuit substrate, a reduction of the pitches of the bonding pads and of the ball terminals is inevitable. In addition, a wire bonding process using a capillary has a limitation in considerably reducing the pitch of bonding pads.

Conventional multilayered circuit substrates may also use vias so as to improve the routing feasibility in designing signal lines. However, the use of vias may result in impedance discontinuity and increased capacitive loading, thereby insufficiently providing high speed efficiency to memory products.

### SUMMARY

Some embodiments of the present invention are directed to increasing the number of bonding pads arranged on a circuit substrate without reducing the pitch of bonding pads.

Additionally, some embodiments of the present invention are directed to increasing the routing feasibility by use of signal wirings instead of vias, thereby corresponding to high speed of memory products.

According to one embodiment of the present invention, a multilayered circuit substrate may include first bonding pads and second bonding pads connected to an integrated circuit chip. The circuit substrate may further include ball lands to be connected to the first bonding pads and the second bonding pads using wirings including signal wirings. The first bonding pads may be provided on a different substrate layer from the second bonding pads. The bonding pads connected to the signal wirings may be provided on the same substrate layer as the corresponding ball lands.

### BRIEF DESCRIPTION OF THE DRAWINGS

The embodiments of the present invention will be readily understood with reference to the following detailed description thereof provided in conjunction with the accompanying drawings, wherein:

FIG. 1 is a plan view of a multilayered circuit substrate in accordance with an embodiment of the present invention.

FIG. 1A is an enlarged plan view of section “A” in FIG. 1.

FIG. 2 is a cross-sectional view taken along line II-II of FIG. 1 illustrating a process for manufacturing a multilayered circuit substrate.

FIG. 3 is a cross-sectional view of an example of a semiconductor package structure using the multilayered circuit substrate embodiment of FIG. 1.

FIG. 4 is a cross-sectional view of another example of a semiconductor package structure using the multilayered circuit substrate embodiment of FIG. 1.

FIG. 5 is a plan view of a multilayered circuit substrate in accordance with another embodiment of the present invention.

FIG. 6 is a plan view of a multilayered circuit substrate in accordance with yet another embodiment of the present invention.

### DETAILED DESCRIPTION

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

It should be noted that the figures are intended to illustrate the general characteristics of methods and devices of example embodiments of this invention, for the purpose of the description of such example embodiments herein. These drawings are not, however, to scale and may not precisely reflect the characteristics of any given embodiment, and should not be interpreted as defining or limiting the range of values or properties of example embodiments within the scope of this invention. Rather, for simplicity and clarity of illustration, the dimensions of some of the elements are exaggerated relative to other elements. The figures, therefore, should not be interpreted as accurately reflecting the relative sizing or positioning of the corresponding structural elements that could be encompassed by an actual device manufactured according to the embodiments of the invention.

Further, well-known structures and processes are not described or illustrated in detail to avoid obscuring the present invention. Like reference numerals are used for like and corresponding parts of the various drawings.

First Embodiment

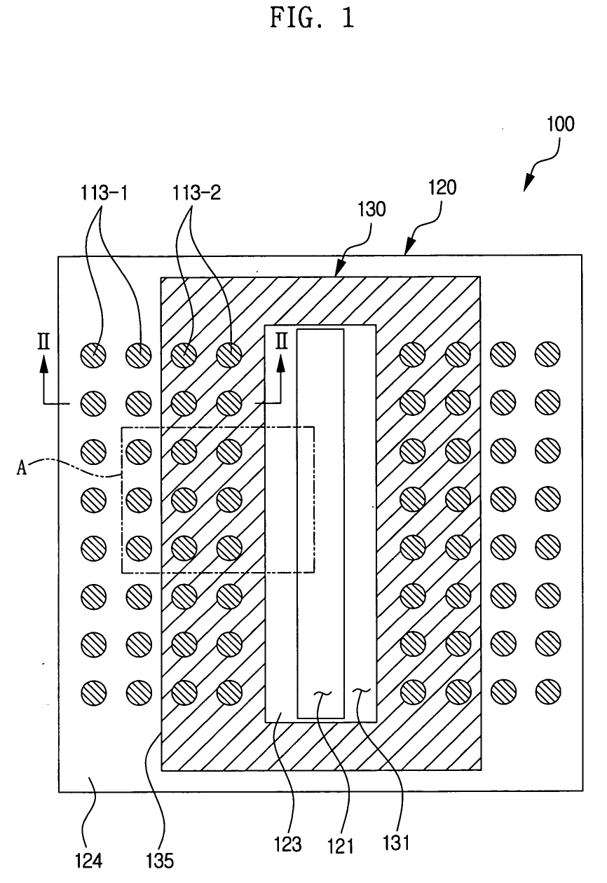

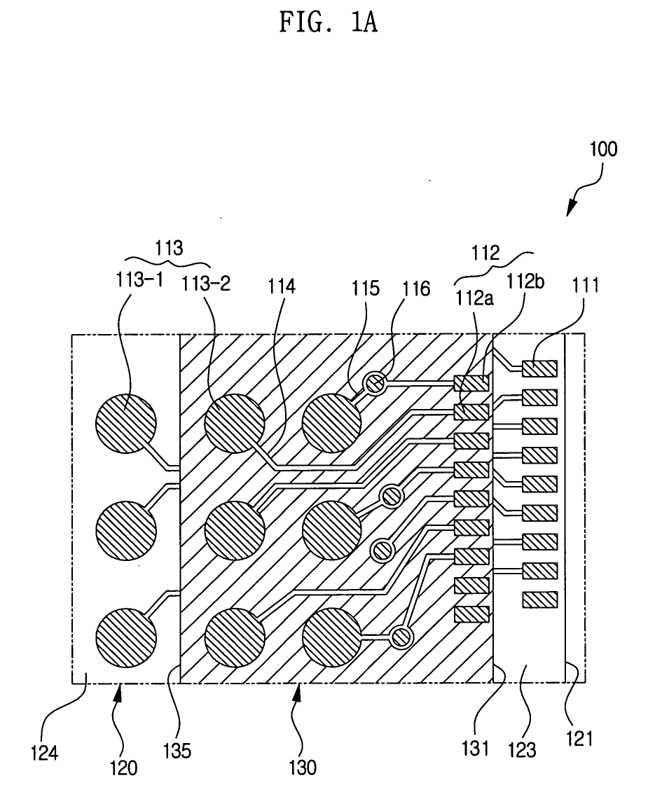

FIG. 1 is a plan view of a multilayered circuit substrate in accordance with an embodiment of the present invention. FIG. 1A is an enlarged plan view of section “A” in FIG. 1.

Referring to FIGS. 1 and 1A, the multilayered circuit substrate 100 may have first bonding pads 111, second bonding pads 112 including 112a and 112b, and ball lands 113 including first ball lands 113-1 and second ball lands 113-2. The first and second bonding pads 111 and 112 may provide electrical connections to an integrated circuit chip during a package fabrication process, and the ball lands 113 may provide a ball terminal attachment area.

The first bonding pads 111 may be arranged on a different layer from the second bonding pads 112. The first and second bonding pads 111 and 112 may be connected to corresponding ball lands 113 using wirings 114 and 115. The wirings 114 and 115 may include signal wirings 114 and power wirings 115.

The second bonding pads 112a connected to the signal wirings 114 may be arranged on the same layer as the corresponding second ball lands 113-2 without vias. The second bonding pads 112b connected to the power wirings 115 may be arranged on a different layer from the corresponding first ball lands 113-1 and may be connected to the corresponding first ball lands 113-1 using vias 116. The first bonding pads 111 may be arranged to be staggered with the second bonding pads 112.

The multilayered circuit substrate 100 may include a first substrate 120 and a second substrate 130. The first substrate 120 may have a first window 121 formed at its center and the second substrate 130 may have a second window 131 formed at its center. The first substrate 120 may have the first bonding pads 111 and the first ball lands 113-1 formed on it, and the second substrate 130 may have the second bonding pads 112 and the second ball lands 113-2 formed on it. The size of the second substrate 130 may be smaller than that of the first substrate 120. The size of the second window 131 may be larger than that of the first window 121. When the second substrate 130 is stacked on the first substrate 120, a region 123 of the first substrate 120 surrounding the first window 121 may be exposed through the second window 131. Peripheral regions 124 of the first substrate 120 may be exposed outside the edges 135 of the second substrate 130.

The first bonding pads 111 may be linearly arranged near the first window 121 and the second bonding pads 112 may be linearly arranged near the second window 131. The first ball lands 113-1 may be arranged over the exposed top surface of the first substrate 120 in the peripheral region 124, and the second ball lands 113-2 may be arranged over the exposed top surface of the second substrate 130. Accordingly, the first and second bonding pads 111 and 112 may be provided on different layers, for example on the first substrate 120 and the second substrate 130, respectively, thereby increasing the number of bonding pads while eliminating the need to reduce the pad pitch. The second bonding pads 112a connected to the signal wirings 114 may be connected to corresponding ball lands 113-2 on the same layer without vias. This may effectively correspond to a high speed operation. Further, as mentioned above, the first bonding pads 111 may be arranged to be staggered with the second bonding pads 112 to reduce the likelihood of an electrical short circuit.

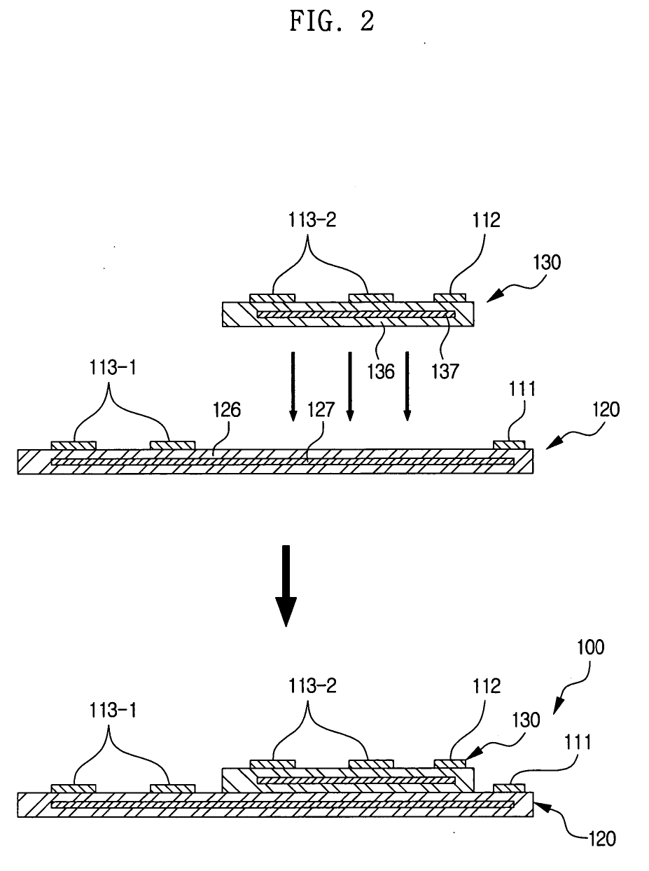

FIG. 2 is a cross-sectional view taken along line II-II of FIG. 1 illustrating a process for manufacturing the multilayered circuit substrate according to an embodiment of the present invention.

Referring to FIG. 2, the first substrate 120 and the second substrate 130 may be stacked to form the multilayered circuit substrate 100. The first and second substrates 120 and 130 may have insulating layers 126 and 136 and copper wiring layers 127 and 137, respectively. A prepreg (not shown) may be used in stacking the second substrate 130 on the first substrate 120 through a thermocompression method.

The thickness of the first substrate 120 may be equal to or different from that of the second substrate 130. The number of the wiring layers 127 of the first substrate 120 may be equal to or different from that of the wiring layers 137 of the second substrate 130. The multilayered circuit substrate 100 may further include at least one substrate similar to the first substrate 120 and/or the second substrate 130.

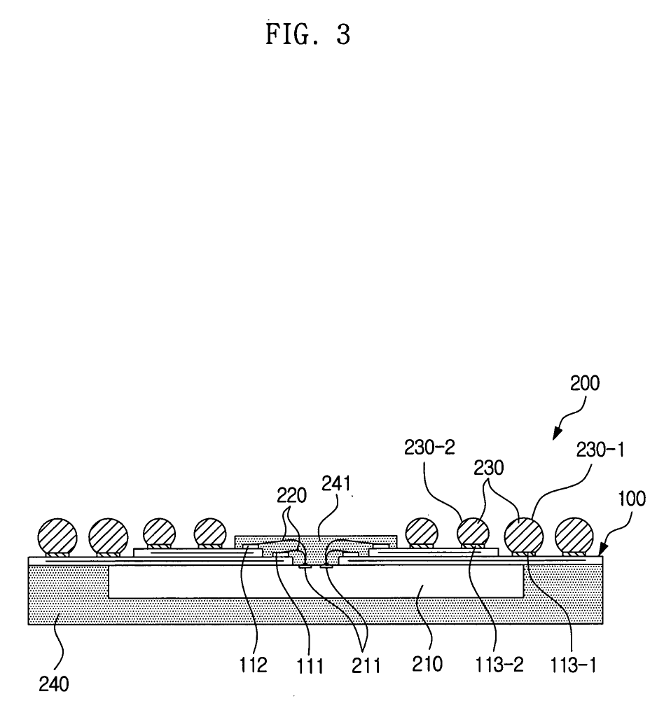

FIG. 3 is a cross-sectional view of an example semiconductor package structure using the multilayered circuit substrate embodiment of FIG. 1.

Referring to FIG. 3, the semiconductor package structure 200 may comprise the multilayered circuit substrate 100 and an integrated circuit chip 210 attached to the multilayered circuit substrate 100. The integrated circuit chip 210 may have chip pads 211 arranged along the center thereof. The chip pads 211 may be exposed through the first and second windows 121 and 131 of the first and second substrates 120 and 130. Bonding wires 220 may electrically connect the chip pads 211 to the multilayered circuit substrate 100. One end of the bonding wire 220 may be connected to the chip pad 211 and the other end of the bonding wire 220 may be connected to the first bonding pads 111 or to the second bonding pads 112. First ball terminals 230-1 may be provided on the first ball lands 113-1 of the multilayered circuit substrate 100, and second ball terminals 230-2 may be provided on the second ball lands 113-2. Encapsulants 240 and 241 may seal the back surface and the side surfaces of the integrated circuit chip 210, the bonding wires 220, and the first and second bonding pads 111 and 112 to protect them from the external environment.

In the semiconductor package structure 200, the size of the first ball terminals 230-1 may be different from that of the second ball terminals 230-2. Because the height of the first ball lands 113-1 is different from that of the second ball lands 113-2, the size of the first ball terminals 230-1 may be formed larger than that of the second ball terminals 230-2, so that the height of the top of the first ball terminals 230-1 may be substantially equal to that of the top of the second ball terminals 230-2.

Although this embodiment shows the first ball terminals 230-1 having a different size from the second ball terminals 230-2, the first ball terminals 230-1 may have the same size as the second ball terminals 230-2.

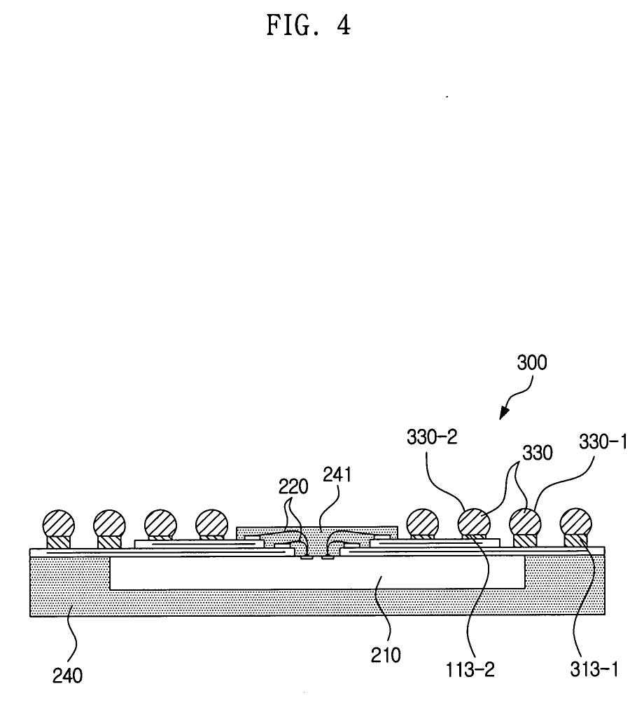

FIG. 4 is a cross-sectional view of another example of a semiconductor package structure using the multilayered circuit substrate embodiment of FIG. 1.

Referring to FIG. 4, a semiconductor package 300 may be formed substantially similar to the semiconductor package illustrated in FIG. 3. However, in the semiconductor package 300 the thickness of first ball lands 313-1 may be increased, for example using a plating method, so that the height of the top of the first ball lands 313-1 may be equal to that of the top of second ball lands 113-2. Therefore, the size of first ball terminals 330-1 on the first ball lands 313-1 may be formed equal to that of second ball terminals 330-2 on the second ball lands 113-2.

Second Embodiment

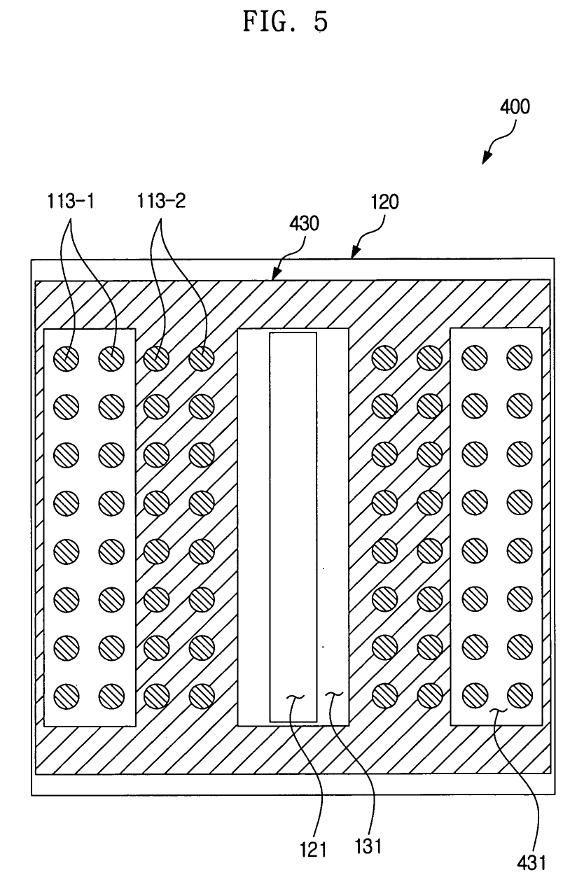

FIG. 5 is a plan view of a multilayered circuit substrate in accordance with another embodiment of the present invention.

Referring to FIG. 5, the multilayered circuit substrate 400 has the same structure as the first embodiment, except for the size and shape of the second substrate.

The multilayered circuit substrate 400 may have a first substrate 120 and a second substrate 430. The first substrate 120 may have a first central window 121, first bonding pads (111 of FIG. 1A) and first ball lands 113-1. The second substrate 430 may have a second central window 131, peripheral windows 431, second bonding pads (112 of FIG. 1A) and second ball lands 113-2.

The size of the second substrate 430 may be similar to that of the first substrate 120. The first ball lands 113-1 of the first substrate 120 may be exposed through the peripheral windows 431 of the second substrate 430.

Third Embodiment

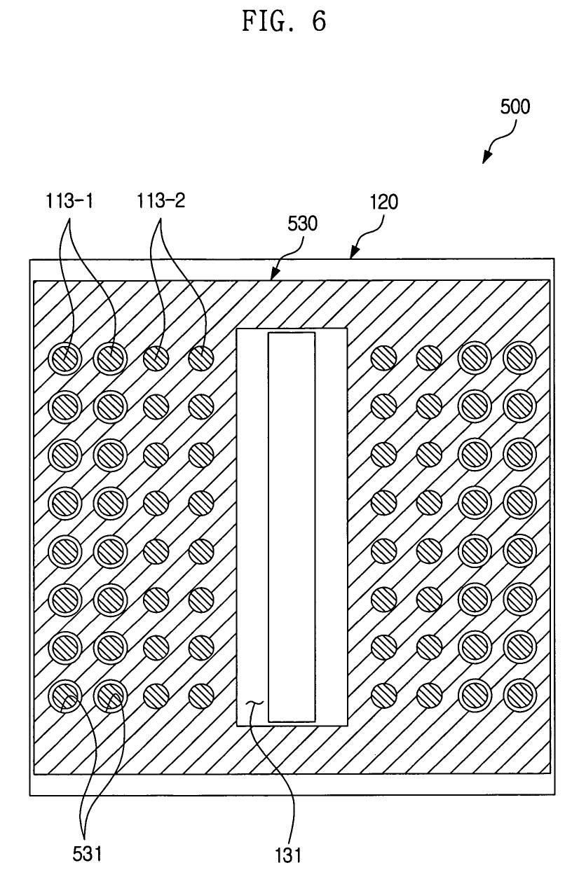

FIG. 6 is a plan view of a multilayered circuit substrate in accordance with yet another embodiment of the present invention.

Referring to FIG. 6, the multilayered circuit substrate 500 may have the same structure as the second embodiment, except for the shape of the second substrate.

A second substrate 530 may have a second central window 131, and a plurality of peripheral windows 531 formed corresponding to the shape of first ball lands 113-1, through which the corresponding first ball lands 113-1 may be exposed.

In accordance with the embodiments of the present invention, the multilayered circuit substrate may have bonding pads provided on different layers. Thereby the number of bonding pads arranged on a circuit substrate may be increased without reducing their pitch. Resultant semiconductor packages may therefore provide better characteristics to match the advancing trends of memory products.

Additionally, bonding pads connected to signal wirings may be arranged on the same layer as corresponding ball lands without vias, which may improve the routing feasibility of high speed memory products.

While this invention has been particularly shown and described with reference to embodiments thereof, it will be understood by those skilled in the art that various changes in form and details may be made therein without departing from the spirit and scope of the invention as defined by the appended claims.

What is claimed is:

1. A multilayered circuit substrate having:
a plurality of first bonding pads and a plurality of second bonding pads; and
a plurality of ball lands, each ball land connected to either one of the first bonding pads or one of the second bonding pads using wirings including signal wirings,
wherein the first bonding pads are provided on a different layer from the second bonding pads, and the bonding pads connected to the signal wirings are provided on the same layer as the corresponding ball lands.

2. The multilayered circuit substrate of claim 1, wherein the first bonding pads are arranged to be staggered with the second bonding pads.

3. A semiconductor package structure comprising:
a multilayered circuit substrate comprising:
a plurality of first bonding pads and a plurality of second bonding pads; and
a plurality of ball lands, each ball land connected to either one of the first bonding pads or one of the second bonding pads using wirings including signal wirings,
wherein the first bonding pads are provided on a different layer from the second bonding pads, and the bonding pads connected to the signal wirings are provided on the same layer as the corresponding ball lands;
an integrated circuit chip attached to the multilayered circuit substrate;
bonding wires connecting the first and second bonding pads of the multilayered circuit substrate to the integrated circuit chip; and
a plurality of ball terminals provided on the ball lands of the multilayered circuit substrate.

4. A multilayered circuit substrate including:
a first substrate having at least one first bonding pad, and at least one first ball land provided on the same layer as the first bonding pad; and
a second substrate having at least one second bonding pad, and at least one second ball land provided on the same layer as the second bonding pad,
wherein the first bonding pads connected to signal wirings are electrically connected to corresponding first ball lands, and the second bonding pads connected to signal wirings are electrically connected to corresponding second ball lands.

5. The multilayered circuit substrate of claim 4, wherein the size of the second substrate is smaller than that of the first substrate.

6. The multilayered circuit substrate of claim 4, wherein a first window is formed at the center of the first substrate and a second window is formed at the center of the second substrate.

7. The multilayered circuit substrate of claim 6, wherein the second window is formed to be larger than the first window to expose the first bonding pads.

8. The multilayered circuit substrate of claim 6, wherein the first bonding pads are linearly arranged near the first window and the second bonding pads are linearly arranged near the second window.

9. The multilayered circuit substrate of claim 4, wherein the first bonding pads are arranged to be staggered with the second bonding pads.

10. The multilayered circuit substrate of claim 4, wherein the size of the second substrate is similar to that of the first substrate.

11. The multilayered circuit substrate of claim 10, wherein the second substrate includes at least one peripheral window, through which the first ball lands are exposed.

12. The multilayered circuit substrate of claim 11, wherein the at least one peripheral window is formed to correspond with the shape of the first ball land.

13. A semiconductor package structure comprising:
a multilayered circuit substrate comprising:
a first substrate having at least one first bonding pad, and at least one first ball land provided on the same layer as the first bonding pad; and
a second substrate having at least one second bonding pad, and at least one second ball land provided on the same layer as the second bonding pad,
wherein the first bonding pads connected to signal wirings are electrically connected to corresponding first ball lands, and the second bonding pads connected to signal wirings are electrically connected to corresponding second ball lands;
an integrated circuit chip attached to the multilayered circuit substrate;
at least one first ball terminal formed on the at least one first ball land of the multilayered circuit substrate; and
at lease one second ball terminal formed on the at least one second ball land of the multilayered circuit substrate.

14. The semiconductor package structure of claim 13, wherein the height of the top of the first ball terminal is the same as that of the top of the second ball terminal.

15. The semiconductor package structure of claim 14, wherein the size of the first ball terminal is larger than that of the second ball terminal.

16. The semiconductor package structure of claim 14, wherein the thickness of the first ball land is larger than that of the second ball land.

17. The semiconductor package structure of claim 16, wherein the size of the first ball terminal is equal to that of the second ball terminal.

18. A method of manufacturing a semiconductor package structure comprising:
forming at least one first bonding pad and at least one first ball land on a first substrate, wherein a first bonding pad corresponding to a signal line is electrically connected with a corresponding first ball land;
forming at least one second bonding pad and at least one second ball land on a second substrate, wherein a second bonding pad corresponding to a signal line is electrically connected with a corresponding second ball land; and
stacking the second substrate on the first substrate.

19. The method of claim 18, wherein the first substrate is stacked on the second substrate using a thermocompression prepreg. 20. The method of claim 18, further comprising:
attaching an integrated chip having chip pads to the stacked first and second substrate;
electrically connecting the chip pads to the first and second bonding pads with bonding wire; and
forming first and second ball terminals on the first and second ball lands, respectively; and forming an encapsulant over the bonding wires and exposed surfaces of the integrated chip.
